(19) United States
(12) Patent Application Publication
(10) Pub. No.: US 2026/0168712 A1
(43) Pub. Date: Jun. 18, 2026

(54) REFRIGERANT CIRCULATION DEVICE

(71) Applicant: NIDEC CORPORATION, Kyoto (JP)

(72) Inventor: Toshihiko TOKESHI, Kyoto (JP)

(21) Appl. No.: 19/411,740

(22) Filed: Dec. 8, 2025

(30) Foreign Application Priority Data
Dec. 13, 2024 (JP) 2024-218843

(51) Int. Cl. F25B 43/00; F25B 41/30; F25B 41/40

(52) U.S. Cl. CPC F25B 43/003; F25B 41/30; F25B 41/40

(57) ABSTRACT

A refrigerant circulation device includes a primary pipe, a secondary pipe, a primary filter, a secondary filter, and a housing. A primary refrigerant flows through the primary pipe. A secondary refrigerant flows through the secondary pipe. The primary filter is connected to the primary pipe. The secondary filter is connected to the secondary pipe. The housing accommodates the primary pipe, the secondary pipe, the primary filter, and the secondary filter. The primary filter and the secondary filter each include a brush and a handle. The brush is located inside the primary filter and the secondary filter. The handle drives the brush. The handle is located at a position opposing the first side surface of the housing.

### CROSS-REFERENCE TO RELATED APPLICATIONS

The present application claims priority under 35 U.S.C. § 119 to Japanese Patent Application No. 2024-218843, filed on Dec. 13, 2024, the entire contents of which are hereby incorporated herein by reference.

### 1. Field of the Invention

Example embodiments described herein relate to refrigerant circulation devices.

### 2. Background

There is a refrigerant circulation device including a primary pipe through which a primary refrigerant flows, a secondary pipe through which a secondary refrigerant flows, a primary filter connected to the primary pipe, a secondary filter connected to the secondary pipe, and a housing for accommodating these components.

However, in cases of the refrigerant circulation device including the housing, maintainability of the components disposed inside the housing may need to be improved.

### SUMMARY

A refrigerant circulation device according to an example embodiment of the present disclosure includes a primary pipe, a secondary pipe, a primary filter, a secondary filter, and a housing. A primary refrigerant flows through the primary pipe. A secondary refrigerant flows through the secondary pipe. The primary filter is connected to the primary pipe. The secondary filter is connected to the secondary pipe. The housing accommodates the primary pipe, the secondary pipe, the primary filter, and the secondary filter. The primary filter and the secondary filter each include a brush and a handle. The brush is located inside the primary filter and the secondary filter. The handle drives the brush. The handle is located at a position opposing a first side surface of the housing.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a block diagram illustrating a configuration example of a refrigerant circulation device according to an example embodiment of the present disclosure.

FIG. 2 is a perspective view of the refrigerant circulation device according to an example embodiment of the present disclosure.

FIG. 3 is a front view of the refrigerant circulation device according to an example embodiment of the present disclosure.

FIG. 4 is a left side view of the refrigerant circulation device according to an example embodiment of the present disclosure.

FIG. 5 is a right side view of the refrigerant circulation device according to an example embodiment of the present disclosure.

FIG. 6 is an explanatory diagram illustrating a connection mode of pumps according to an example embodiment of the present disclosure.

FIG. 7 is an explanatory view taken from a peripheral portion of the pumps according to an example embodiment of the present disclosure.

FIG. 8 is an explanatory diagram of a primary filter and an external filter device according to an example embodiment of the present disclosure.

### DETAILED DESCRIPTION

Hereinafter, refrigerant circulation devices according to example embodiments of the present disclosure will be described in detail with reference to the drawings. The present disclosure is not limited by the example embodiments. The example embodiments can be combined as appropriate. In the following example embodiments, components having the same function are denoted by the same reference numerals, and redundant description thereof will be omitted.

In the example embodiments described below, expressions such as “constant”, “orthogonal”, “perpendicular”, and “parallel” may be used, but these expressions do not necessarily mean “constant”, “orthogonal”, “perpendicular”, and “parallel” in a strict sense. That is, each of the above expressions allows for deviations in, for example, manufacturing accuracy, and installation accuracy.

In addition, in each of the drawings referred to below, in order to make the description easy to understand, an orthogonal coordinate system may be indicated by defining an X-axis direction, a Y-axis direction, and a Z-axis direction orthogonal or substantially orthogonal to each other and setting a Z-axis positive direction as a vertically upward direction.

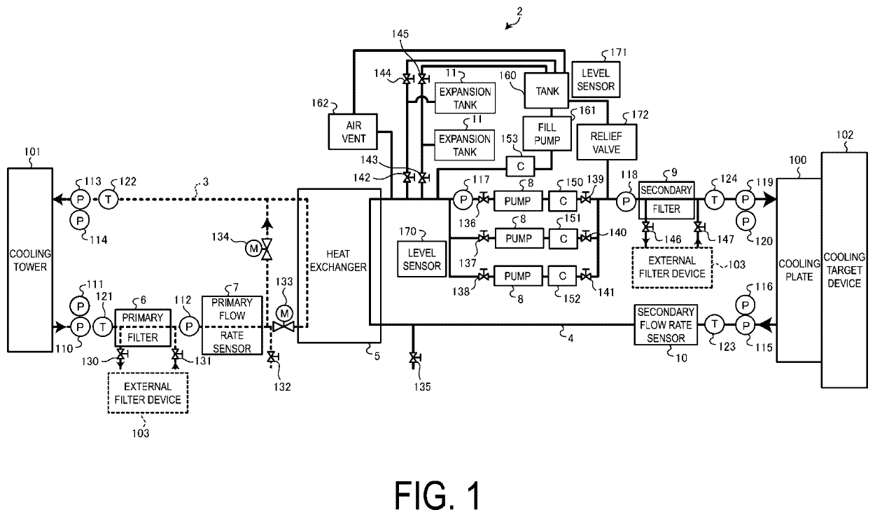

FIG. 1 is a block diagram illustrating a configuration example of a refrigerant circulation device 2 according to an example embodiment. In FIG. 1, some components such as a pressure sensor for detecting a pressure of a refrigerant and a valve provided in a circulation path of the refrigerant are not illustrated.

The refrigerant circulation device 2 is a device that circulates the primary refrigerant and the secondary refrigerant in order to cool a cooling target device 102. The cooling target device 102 is a device which generates heat, such as a central processing unit (CPU). The cooling target device 102 is not limited to the CPU.

The refrigerant circulation device 2 includes a primary pipe 3 through which the primary refrigerant flows and a secondary pipe 4 through which a secondary refrigerant flows. In FIG. 1, the primary pipe 3 is indicated by a thick dotted arrow, and the secondary pipe 4 is indicated by a thick solid arrow. The primary pipe 3 is connected to a cooling tower 101. The cooling tower 101 is a device that cools the primary refrigerant flowing in from the refrigerant circulation device 2 and delivers the cooled primary refrigerant to the refrigerant circulation device 2 to circulate the primary refrigerant.

The secondary pipe 4 is connected to a cooling plate 100. The cooling plate 100 is attached to the cooling target device 102. The refrigerant circulation device 2 delivers the secondary refrigerant to the cooling plate 100. The secondary refrigerant that has absorbed heat from the cooling target device 102 in a process of passing through the cooling plate 100 flows into the refrigerant circulation device 2.

The refrigerant circulation device 2 can be connected to a plurality of the cooling plates 100. The refrigerant circulation device 2 can be connected to a plurality of the cooling target devices 102. The refrigerant circulation device 2 can be connected to a plurality of server racks.

In this case, an outward path of the secondary pipe 4 through which the secondary refrigerant flows from the refrigerant circulation device 2 toward the server rack is distributed to the plurality of server racks, and then further distributed to the plurality of cooling plates 100. Then, the return path of the secondary pipes 4 through which the secondary refrigerant flows from the server racks toward the refrigerant circulation device 2 is formed by flows from the plurality of cooling plates 100, and from the plurality of server racks and is connected to the refrigerant circulation device 2.

The refrigerant circulation device 2 includes a heat exchanger 5. The heat exchanger 5 is a device that cools the secondary refrigerant by causing the primary refrigerant to absorb the heat of the secondary refrigerant flowing in from the cooling plate 100. The refrigerant circulation device 2 cools the cooling target device 102 by returning the secondary refrigerant cooled by the heat exchanger 5 to the cooling plate 100.

The refrigerant circulation device 2 includes a primary filter 6, a primary flow rate sensor 7, a pump 8, a secondary filter 9, a secondary flow rate sensor 10, an expansion tank 11, a display 12, and the like. The primary filter 6 is connected to the primary pipe 3. The primary filter 6 filters the primary refrigerant flowing through the primary pipe 3 to remove foreign matter from the primary refrigerant.

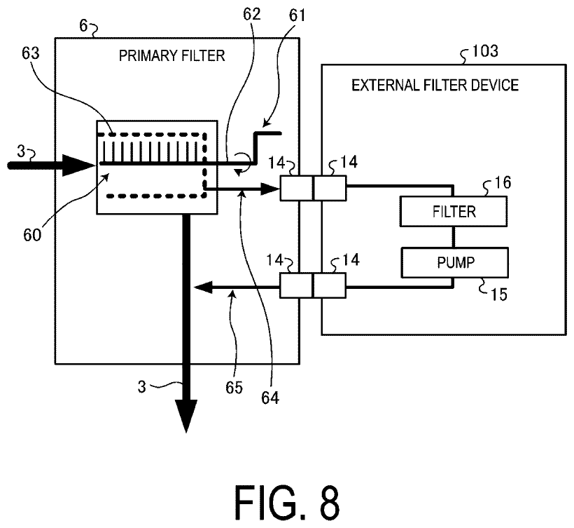

The primary filter 6 includes a primary brush 60, which will be described later, disposed inside the primary filter 6, and a primary handle 61 for driving the primary brush 60 (see FIG. 8). In the primary filter 6, the primary brush 60 is rotated by rotating the primary handle 61, and thus the inside of the filter is cleaned.

In one example, the primary brush 60 rotates to peel off foreign matter adhering to the inside of the filter from the filter. The peeled off foreign matter is removed by an external filter device 103 (see FIG. 8) described later, or is removed from the secondary pipe 4 by being discharged to the outside of the primary filter 6 together with the primary refrigerant.

In one example, the timing of cleaning the primary filter 6 is determined based on a pressure of the primary refrigerant detected by the pressure sensors 110 and 111 provided upstream of the primary filter 6 and the pressure sensor 112 provided downstream of the primary filter 6. When the primary filter 6 is clogged, a flow path resistance of the primary refrigerant in the primary filter 6 increases, and a pressure difference of the primary refrigerant between the upstream and downstream of the primary filter 6 increases.

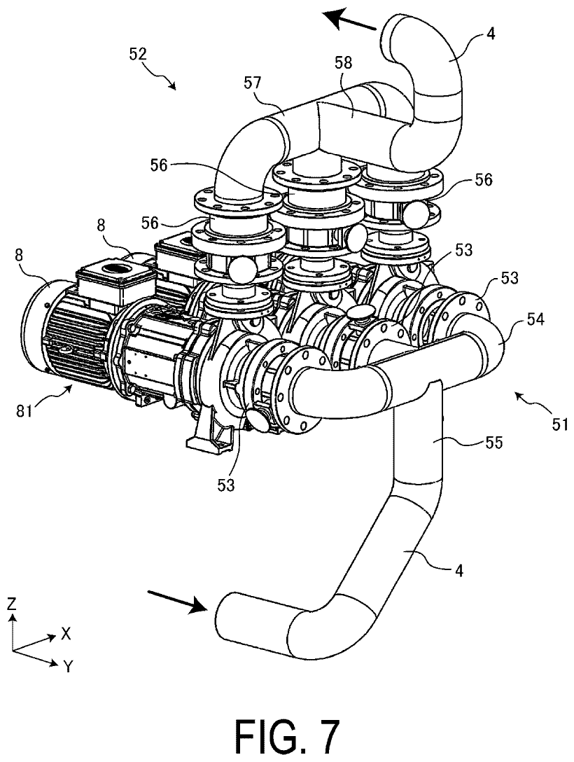

Thus, in one example, a controller (not illustrated) of the refrigerant circulation device 2 can notify a user of a maintenance request when the difference between the pressures of the primary refrigerant detected by the pressure sensors 110 and 111 provided upstream of the primary filter 6 and the pressure sensor 112 provided downstream of the primary filter 6 reaches a certain level (threshold value) or more. In one example, the controller causes the display 12 to display a notification of maintenance request. A configuration example of the primary filter 6 will be described with reference to FIG. 7 together with the configuration of the external filter device 103 described later.

The primary flow rate sensor 7 detects the flow rate of the primary refrigerant flowing through the primary pipe 3. The primary flow rate sensor 7 outputs the detected flow rate of the primary refrigerant to the display 12. The display 12 displays information such as the flow rate of the primary refrigerant indicating an operation state of the refrigerant circulation device 2.

The pump 8 delivers the secondary refrigerant cooled by the heat exchanger 5 toward the cooling plate 100. In the example illustrated in FIG. 1, three pumps 8 are connected in parallel or substantially parallel to the secondary pipe 4. The secondary filter 9 filters the secondary refrigerant flowing through the secondary pipe 4 to remove foreign matter from the secondary refrigerant.

The secondary filter 9 has the same configuration as the primary filter 6. That is, the secondary filter 9 includes a secondary brush disposed inside the secondary filter 9 and a secondary handle for driving the secondary brush. In the secondary filter 9, the secondary brush is rotated by rotating the secondary handle and thus the inside of the filter is cleaned.

A method of cleaning the secondary filter 9, a method of determining the timing of cleaning, and a method of notification of the maintenance request are the same as those for the primary filter 6. Thus, redundant description of the method of cleaning the secondary filter 9, the method of determining the timing of cleaning, and the method of notification of the maintenance request will be omitted.

The secondary flow rate sensor 10 detects the flow rate of the secondary refrigerant flowing through the secondary pipe 4. The secondary flow rate sensor 10 outputs the detected flow rate of the secondary refrigerant to the display 12. The display 12 displays information such as the flow rate of the secondary refrigerant indicating an operation state of the refrigerant circulation device 2.

The expansion tank 11 is connected to the secondary pipe 4. The expansion tank 11 includes regulating valves 142 and 143 for regulating a pressure inside the expansion tank 11. The expansion tank 11 regulates a pressure of the secondary refrigerant flowing through the secondary pipe 4 by regulating an opening degree of the regulating valves 142 and 143.

A predetermined filling pressure is applied to the expansion tank 11 in advance. When the refrigerant is thermally expanded, the pressure of the secondary refrigerant increases. In this case, the regulating valves 142 and 143 provided on an upstream side of the expansion tank 11 are opened. At this time, when the pressure of the secondary refrigerant is higher than the filling pressure of the expansion tank 11, the secondary refrigerant flows from the secondary pipe 4 into the expansion tank 11 until the pressure of the secondary refrigerant becomes equal to the filling pressure. In this way, the expansion tank 11 can suppress damage to the secondary pipe 4 due to an increase in the internal pressure by absorbing the expanded amount of the secondary refrigerant.

When the internal pressure of the expansion tank 11 decreases, valves 144 and 145 provided between the expansion tank 11 and the tank 160 are opened. Then, the secondary refrigerant pressurized by a fill pump 161 is pressed into the expansion tank 11 from the tank 160 until the internal pressure of the expansion tank 11 reaches a predetermined filling pressure. Thus, entry of a gas into the expansion tank 11 can be suppressed.

In addition, the refrigerant circulation device 2 is provided with the pressure sensors 110 and 111 and a temperature sensor 121 at an inflow portion into which the primary refrigerant flows from the cooling tower 101. The pressure sensor 112 is provided between the primary filter 6 and the primary flow rate sensor 7. Pressure sensors 113 and 114 and a temperature sensor 122 are provided at an outflow portion from which the primary refrigerant flows out to the cooling tower 101.

The primary pipe 3 includes a bypass flow path that extends from the downstream side of the primary filter 6 to an outflow port instead of extending to the heat exchanger 5. An electric valve 134 is provided in the bypass flow path. By regulating the opening degree of the electric valve 134, the flow rate of the primary refrigerant flowing into the heat exchanger 5 can be regulated by the bypass flow path. An electric valve 133 is provided between the primary flow rate sensor 7 and the heat exchanger 5.

In addition, a plurality of valves 130, 131, and 132 are provided in the primary pipe 3. The valves 130 and 131 are connected to the external filter device 103 (see FIG. 8) described later. The valve 132 can discharge the primary refrigerant from the upstream side of the heat exchanger 5 in the primary pipe 3 to the outside of the refrigerant circulation device 2 by being opened.

In addition, the refrigerant circulation device 2 is provided with pressure sensors 115 and 116 and a temperature sensor 123 at an inflow portion into which the secondary refrigerant flows from the cooling plate 100. Pressure sensors 119 and 120 and a temperature sensor 124 are provided at an outflow portion from which the secondary refrigerant flows out to the cooling plate 100.

A pressure sensor 117 is provided between the secondary flow rate sensor 10 and the pump 8. Check valves 150, 151, and 152 are provided to the downstream side of a respective one of the pumps 8. A pressure sensor 118 is provided between the check valves 150, 151, and 152 and the secondary filter 9.

The secondary pipe 4 is provided with a plurality of valves 135, 136, 137, 138, 139, 140, 141, 146, and 147. The valve 135 is provided between the secondary flow rate sensor 10 and the heat exchanger 5. The valve 135 can discharge the secondary refrigerant from the upstream side of the heat exchanger 5 in the secondary pipe 4 to the outside of the refrigerant circulation device 2 by being opened.

The valves 136, 137, 138, 139, 140, and 141 are normally opened and, are closed, for example, when the pumps 8 are being inspected or replaced. The valves 146 and 147 are connected to the external filter device 103 (see FIG. 8) described later. The above-described regulating valves 142 and 143 are provided between the heat exchanger 5 and the expansion tank 11.

The expansion tank 11 is disposed between the downstream of the heat exchanger 5 and the upstream of the pump 8. Thus, even when, for example, a negative pressure is generated on the upstream side of the pump 8, the refrigerant circulation device 2 can regulate the pressure on the upstream side of the pump 8 by the expansion tank 11, and thus can prevent the pump 8 from being damaged by cavitation.

The refrigerant circulation device 2 is provided with the fill pump 161 and a check valve 153 between the tank 160 and the pump 8. When the internal pressure of the tank 160 decreases, the fill pump 161 increases the internal pressure by pressing the secondary refrigerant into the tank 160. In addition, the refrigerant circulation device 2 can suppress the refrigerant, which is pumped from the fill pump 161, flowing to the tank 160 side and looping within the refrigerant circulation device 2 by closing the check valve 153.

The refrigerant circulation device 2 includes an air vent 162 between the heat exchanger 5 and the tank 160. The air vent 162 releases air that has entered the secondary pipe 4 to the outside of the refrigerant circulation device 2. The refrigerant circulation device 2 includes level sensors 170 and 171 for detecting the amount of the secondary refrigerant in the tank 160, and a relief valve 172. When the amount of the secondary refrigerant in the tank 160 exceeds a threshold value, the refrigerant circulation device 2 releases the secondary refrigerant from the tank 160 to the secondary pipe 4 by the relief valve 172.

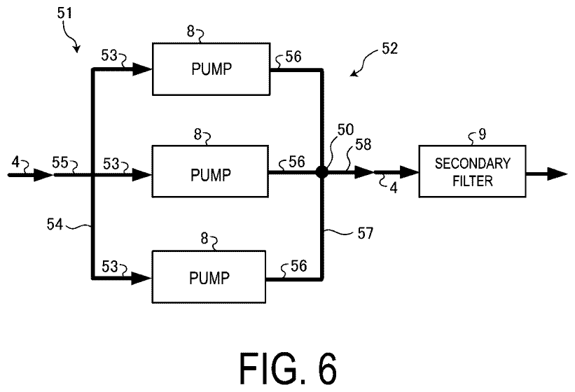

The level sensor 170 is provided in a collecting pipe 54 (see FIGS. 6 and 7) described later. The level sensor 170 measures a water level of the secondary refrigerant at an inflow port of the pump 8 in order to suppress idling of the pump 8. The refrigerant circulation device 2 can stop an operation of the pump 8 when the water level of the secondary refrigerant is a threshold value or less.

The level sensor 171 measures the water level of the secondary refrigerant in the tank 160. The refrigerant circulation device 2 can make a notification to urge replenishment of the secondary refrigerant by, for example, the display 12 when the water level of the secondary refrigerant in the tank 160 falls below the threshold value.

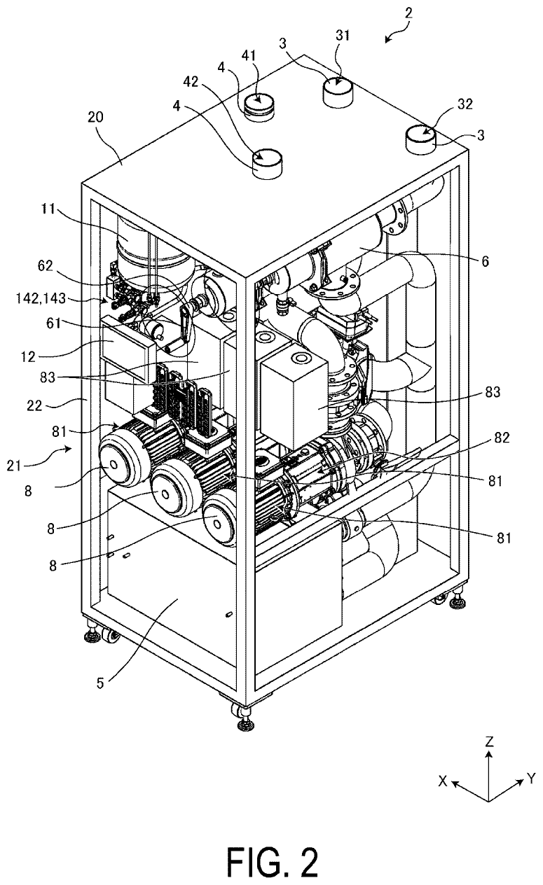

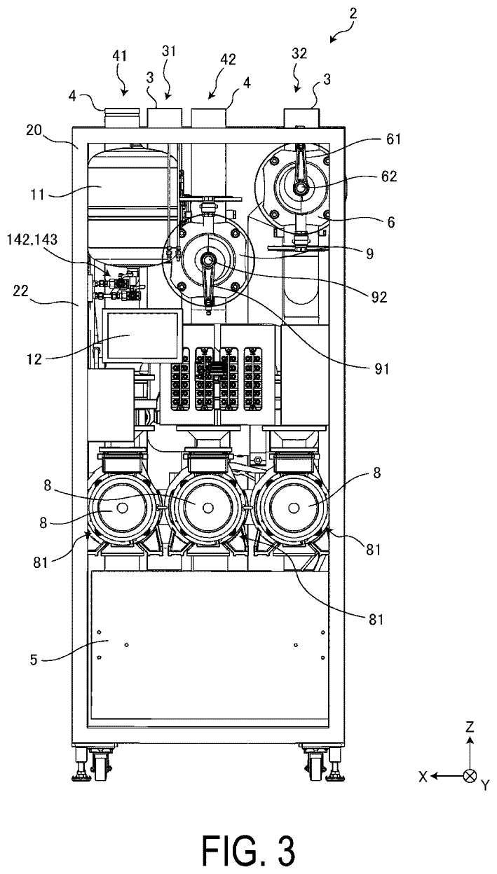

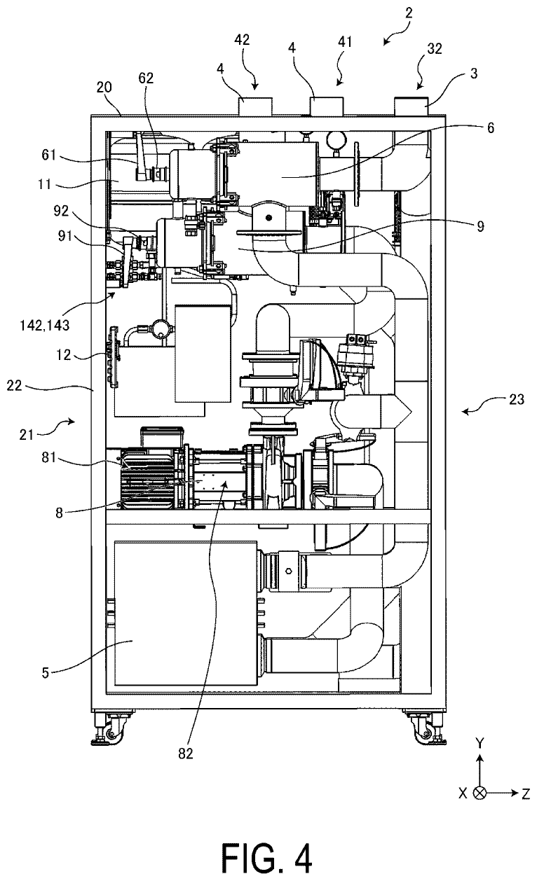

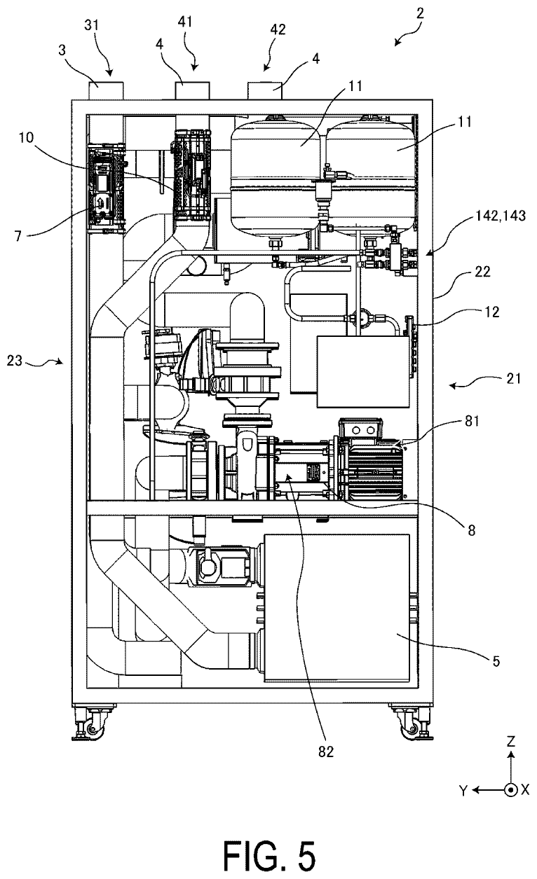

Next, an arrangement example of the components of the refrigerant circulation device 2 will be described with reference to FIGS. 2 to 5. FIG. 2 is a perspective view of the refrigerant circulation device 2 according to the example embodiment. FIG. 3 is a front view of the refrigerant circulation device 2 according to the example embodiment. FIG. 4 is a left side view of the refrigerant circulation device 2 according to the example embodiment. FIG. 5 is a right side view of the refrigerant circulation device 2 according to the example embodiment.

As illustrated in FIGS. 2 to 5, each component of the refrigerant circulation device 2 is accommodated in a housing 20 having a box shape. That is, the primary pipe 3, the secondary pipe 4, the primary filter 6, the primary flow rate sensor 7, the pump 8, the secondary filter 9, the secondary flow rate sensor 10, the expansion tank 11, and the display 12 of the refrigerant circulation device 2 are accommodated inside the housing 20. An inflow port 31 for the primary refrigerant, an outflow port 32 for the primary refrigerant, an inflow port 41 for the secondary refrigerant, and an outflow port 42 for the secondary refrigerant are disposed in a top plate of the housing 20.

Among the components of the refrigerant circulation device 2, the primary handle 61 of the primary filter 6 and the secondary handle 91 of the secondary filter 9 are disposed at positions facing the first side surface 21, which is the front surface of the housing 20, as illustrated in FIGS. 2 and 3. Here, the positions facing the first side surface 21 of the housing 20 are positions where nothing is interposed between the primary handle 61 and the secondary handle 91 and the first side surface 21 of the housing 20.

The first side surface 21 of the housing 20 is a door 22 that is openable and closable. Thus, a worker who performs maintenance work of the refrigerant circulation device 2 (hereinafter, simply referred to as “worker”) can open the door 22 and rotate the primary handle 61 and the secondary handle 91 disposed on a frontmost side. Thus, the worker can easily perform maintenance work of the primary filter 6 and the secondary filter 9.

As illustrated in FIGS. 2 to 5, the regulating valves 142 and 143 of the expansion tank 11 are disposed at positions facing the first side surface 21 of the housing 20. Here, the positions facing the first side surface 21 of the housing 20 are positions where nothing is interposed between the regulating valves 142 and 143 and the first side surface 21 of the housing 20. Thus, the worker can easily perform the pressure regulation work inside the expansion tank 11.

As illustrated in FIG. 5, the primary flow rate sensor 7 and the secondary flow rate sensor 10 are disposed at positions facing the first side surface 21 of the housing 20 and facing a second side surface 23, which is the back surface of the housing 20. Here, the positions facing the second side surface 23 of the housing 20 are positions where nothing is interposed between the primary flow rate sensor 7 and the secondary flow rate sensor 10 and the second side surface 23 of the housing 20. Other devices may be disposed on the side surfaces (left and right side surfaces) other than the first side surface 21, which is the front surface of the housing 20, and the second side surface 23, which is the back surface of the housing 20, other devices are not likely to be disposed on the back surface side of the housing 20.

In the refrigerant circulation device 2, all of the inflow port and outflow port of the refrigerant of the heat exchanger 5 are provided on the second side surface 23 side, and a suction port of the pump 8 is provided on the second side surface 23 side. Thus, in the refrigerant circulation device 2, the primary pipe 3 and the secondary pipe 4 both can be disposed on the second side surface 23 side, and thus, at the time of maintenance of the primary pipe 3 and the secondary pipe 4, the work can be performed from the second side surface 23 side at once, and work efficiency is improved.

Thus, when the primary flow rate sensor 7 and the secondary flow rate sensor 10 are disposed at the positions facing the second side surface 23, which is the back surface of the housing 20, the worker can easily perform replacement work of the primary flow rate sensor 7 and the secondary flow rate sensor 10 by going around to the back of the housing 20.

As illustrated in FIGS. 2 and 3, a punched metal that allows the inside of the housing 20 to be visually recognized is used for the door 22 of the housing 20. Note that, any material, for example, glass, may be used for the door 22 as long as the inside of the housing 20 is visually recognizable. As illustrated in FIGS. 2 to 5, the display 12 is disposed on an outer surface of the door 22 in a state where a display surface faces the outside of the housing 20. Thus, the worker can check the display 12 from outside the housing 20, and can easily perform maintenance by opening the door 22.

The display 12 may have a touch panel function and enable input operation. The display 12 may be disposed closer to the inner side of the housing 20 than the door 22. In one example, the door 22 includes a hinge having a rotation shaft extending in a direction parallel or substantially parallel to the Z-axis direction on one side in the X-axis direction of the first side surface 21 of the housing 20, and is configured to be openable and closable with the rotation shaft as a rotation center. In this case, the display 12 may be disposed on the other side in the X-axis direction inside the housing 20. Thus, the door 22 can reduce the amount of opening and closing operations of the door 22 performed before and after the input operation to the display 12.

The pump 8 according to the example embodiment is a magnet pump, and includes a motor assembly 81 including a motor, and a pump unit 82 connected to the flow path and pumping the refrigerant by an impeller, and the motor assembly 81 and the pump unit 82 are separably connected to each other.

As illustrated in FIGS. 2 to 5, in each pump 8, the motor assembly 81 of the pump 8 is disposed at a position facing the first side surface 21 of the housing 20. Here, the position facing the first side surface 21 of the housing 20 is a position where nothing is interposed between the motor assembly 81 of the pump 8 and the first side surface 21 of the housing 20. Thus, when the motor assembly 81 of the pump 8 fails, the worker can easily replace the motor assembly 81.

As illustrated in FIGS. 2 to 5, the heat exchanger 5 is disposed at a position lower than the pumps 8 inside the housing 20. Preferably, the heat exchanger 5 is disposed at the lowermost portion of the housing 20. In this way, in the refrigerant circulation device 2, the heat exchanger 5, which is heavier than the other components, is disposed at a position close to the bottom portion in the housing 20, and thus the heat exchanger 5 can be easily held and the stability of the housing 20 can be improved.

In the refrigerant circulation device 2, the heat exchanger 5 is disposed at the lowermost end in the housing 20, and the pumps 8 are disposed above the heat exchanger 5. The pumps 8 are not directly disposed on the heat exchanger 5, but are disposed on a holding plate member extending from a beam provided in the housing 20.

In the refrigerant circulation device 2, the heat exchanger 5 is disposed below the housing 20, and the inflow port 31 for the primary refrigerant, the outflow port 32 for the primary refrigerant, the inflow port 41 for the secondary refrigerant, and the outflow port 42 for the secondary refrigerant are disposed on an upper surface of the housing 20. Thus, in the refrigerant circulation device 2, the lengths of the primary pipe 3 and the secondary pipe 4 can be increased, routing is facilitated and connection with other members is facilitated.

As illustrated in FIGS. 2 and 3, the primary handle 61 of the primary filter 6, the secondary handle 91 of the secondary filter 9, and the regulating valves 142 and 143 of the expansion tank 11 are disposed at positions higher than a center of the housing 20 in the height direction. Thus, the worker can operate the primary handle 61, the secondary handle 91, and the regulating valves 142 and 143 in a comfortable posture without bending forward greatly.

As illustrated in FIG. 3, the primary handle 61 and the secondary handle 91 are disposed at different levels with their positions in the X-axis direction and the Y-axis direction being shifted from each other. As described above, in the refrigerant circulation device 2, rotating positions of the primary handle 61 and the secondary handle 91 are shifted from each other, and thus, even when the primary handle 61 and the secondary handle 91 are operated at the same time, contact of the primary handle 61 and the secondary handle 91 with each other can be suppressed. In the refrigerant circulation device 2, the primary filter 6 and the secondary filter 9 can be brought closer to each other in the X-axis direction and the Y-axis direction by such an arrangement of the primary handle 61 and the secondary handle 91.

As illustrated in FIGS. 3 and 4, in the primary handle 61, an extending direction of a rotation shaft 62 of the primary handle 61 is a horizontal direction. In the secondary handle 91, an extending direction of a rotation shaft 92 of the secondary handle 91 is the horizontal direction. The extending directions of the rotation shafts 62 and 92 are preferably parallel or substantially parallel to each other.

Thus, in the refrigerant circulation device 2, the rotation shaft 62 of the primary handle 61 and the rotation shaft 92 of the secondary handle 91 are less likely to interfere with other components, which can save space as compared with a case where the rotation shafts 62 and 92 are obliquely disposed.

Next, a connection mode of the pumps 8 will be described with reference to FIG. 6. FIG. 6 is an explanatory diagram illustrating a connection mode of the pumps 8 according to the example embodiment. As illustrated in FIG. 6, the three pumps 8 are connected in parallel or substantially parallel to the secondary pipe 4. The three pumps 8 are arranged side by side along a first direction (for example, the X-axis direction illustrated in FIG. 1).

The refrigerant circulation device 2 includes a first pipe 51 for connecting inflow portions of the secondary refrigerant in the plurality of pumps 8 and the secondary pipe 4 to each other, and a second pipe 52 for connecting outflow portions of the secondary refrigerant in the plurality of pumps 8 and the secondary pipe 4 to each other. The first pipe 51 includes extension pipes 53, a collecting pipe 54, and a connecting pipe 55. The second pipe 52 includes extension pipes 56, a collecting pipe 57, and a connecting pipe 58.

FIG. 7 is an explanatory view of a peripheral portion cut out from the pumps 8 according to the example embodiment. In FIG. 7, a direction in which the secondary refrigerant flows is indicated by a thick arrow. As illustrated in FIG. 7, the first pipe 51 is a pipe that branches into three pipes and causes the secondary refrigerant to flow into the inflow port of each pump 8 from the horizontal direction (direction parallel or substantially parallel to the Y-axis).

The extension pipes 53 of the first pipe 51 extend from the pumps 8 in a second direction (for example, the Y-axis direction illustrated in FIG. 1) orthogonal or substantially orthogonal to the first direction. The collecting pipe 54 of the first pipe 51 extends in a direction parallel or substantially parallel to the first direction and is connected to a plurality of the extension pipes 53. The connecting pipe 55 of the first pipe 51 extends from the collecting pipe 54 in a direction (vertical direction: normal direction of an X-Y plane) orthogonal or substantially orthogonal to the first direction and the second direction, and connects the collecting pipe 54 and the secondary pipe 4 to each other.

The second pipe 52 includes a flow path extending in the vertical direction from the outflow port of each pump 8 and merging the three branches. The extension pipes 56 of the second pipe 52 extend from the pumps 8 in a direction (vertical direction: normal direction of the X-Y plane) orthogonal or substantially orthogonal to the first direction and the second direction. The collecting pipe 57 of the second pipe 52 extends in a direction parallel or substantially parallel to the first direction and is connected to a plurality of the extension pipes 56. The connecting pipe 58 of the second pipe 52 extends from the collecting pipe 57 in a second direction (for example, the Y-axis direction illustrated in FIG. 1) orthogonal or substantially orthogonal to the first direction, and connects the collecting pipe 57 and the secondary pipe 4 to each other.

Thus, in the refrigerant circulation device 2, for example, inverters 83 (see FIG. 2) for the pumps 8 can be disposed in a space on the first side surface 21 side defined by the motor assemblies 81 of the pumps 8 and the extension pipe 56 of the second pipe 52 extending from the pumps 8 in the vertical direction.

In addition, the collecting pipes 54 and 57, which are three branch flow paths for merging and branching, can contribute to space saving by the flow path pipe at the center extending straight and the flow path pipes on both sides being bent by 90 degrees and connected to the flow path at the center.

In addition, when the collecting pipes 54 and 57 are connected to the connecting pipes 55 and 58, at one end portion, the flow path of the pump 8 connected to the other end portion via the extension pipes 53 and 56 is longer than the flow paths of the other pumps 8.

In contrast, the collecting pipes 54 and 57 according to the example embodiment are connected to the connecting pipes 55 and 58 at the central portions, in the length direction, and thus, an increase in the length of the flow path of one pump 8 can be suppressed.

In the refrigerant circulation device 2, flow paths connected to the inflow port and outflow port of the refrigerant in the heat exchanger 5 and a flow path pipe connected to the outside of the refrigerant circulation device 2 are arranged on the second side surface 23 side of the flow path connected to the inflow port of the pump 8 (see FIGS. 4 and 5). Thus, the refrigerant circulation device 2 can achieve the space saving and suppress complication of piping.

The second pipe 52 connected to the pumps 8 functions as a merging pipe that merges the secondary refrigerant output from the three pumps 8. The secondary filter 9 is connected to a downstream side of a merging point 50 of the secondary refrigerant in the second pipe 52 functioning as the merging pipe. Thus, the refrigerant circulation device 2 can pass all the secondary refrigerant circulating through the secondary pipe 4 through the secondary filter 9.

Next, the primary filter 6, the secondary filter 9, and the external filter device 103 will be described with reference to FIG. 8. The primary filter 6 and the secondary filter 9 have the same configuration. Thus, the configurations of the primary filter 6 and the external filter device 103 will be described, and redundant description on the configuration of the secondary filter 9 will be omitted.

As illustrated in FIG. 8, the primary filter 6 includes a filter portion 63, a discharge portion 64, and a return portion 65. The primary brush 60 is disposed inside the filter portion 63. The primary refrigerant is discharged from the filter portion 63 toward the external filter device 103 through the discharge portion 64. Specifically, the primary refrigerant flowing into the primary filter 6 passes through the filter portion 63 and is then discharged from the primary filter 6.

The external filter device 103 collects foreign matter accumulated in the primary filter 6. The refrigerant circulation device 2 can eliminate clogging of the primary filter 6 even during operation of the refrigerant circulation device 2 by attaching the external filter device 103 to the primary filter 6. A flow path for discharging the primary refrigerant from the primary filter 6 to the external filter device 103 is a flow path different from a flow path for circulating the primary refrigerant in a normal state.

The return portion 65 returns the filtered primary refrigerant returned from the external filter device 103 for filtering the primary refrigerant discharged from the discharge portion 64 to the primary pipe 3. In this way, the refrigerant circulation device 2 filters the primary refrigerant discharged from the primary filter 6 by the external filter device 103 and returns the primary refrigerant to the primary pipe 3, and thus, a waste liquid of the primary refrigerant can be reduced.

The discharge portion 64 and the return portion 65 of the primary filter 6 and the discharge portion and the return portion of the secondary filter 9 are disposed at positions facing the first side surface 21 of the housing 20. Here, the positions facing the first side surface 21 of the housing 20 are positions where nothing is interposed between the discharge portion 64 and the return portion 65 and the first side surface 21 of the housing 20. Thus, the worker can attach and detach the external filter device 103 from the front side of the refrigerant circulation device 2, and thus can easily perform the maintenance work using the external filter device 103.

The discharge portion 64 and the return portion 65 of the primary filter 6 and the discharge portion and the return portion of the secondary filter 9 are connected to the external filter device 103 via couplings 14. Thus, the worker can easily attach and detach the external filter device 103.

The return portion 65 of the primary filter 6 is provided on a downstream side of a connection position of the primary filter 6 in the primary pipe 3. The return portion of the secondary filter 9 is provided on a downstream side of a connection position of the secondary filter 9 in the secondary pipe 4.

Thus, the refrigerant circulation device 2 can suppress circulation of the primary refrigerant on the upstream side of the primary filter 6 that makes it difficult for the primary refrigerant to flow into the primary filter 6. The refrigerant circulation device 2 can also suppress circulation of the secondary refrigerant on the upstream side of the secondary filter 9 that makes it difficult for the secondary refrigerant to flow into the secondary filter 9.

The external filter device 103 includes a filter 16 and a pump 15 connected in series to a pipe through which the refrigerant flows. The filter 16 of the external filter device 103 is provided on an upstream side of a connection position of the pump 15 in the pipe. Thus, the external filter device 103 can suppress entry of foreign matter into the pump 15.

In addition, in the case where the pump 15 is not provided in the external filter device 103, when the filter 16 is clogged and the flow path resistance increases, the primary refrigerant may not circulate from the primary filter 6 side to the external filter device 103 side having a high flow path resistance, and thus the foreign matter may not be discharged. Thus, the external filter device 103 includes the pump 15. Thus, the external filter device 103 can circulate the primary refrigerant from the primary filter 6 side to the external filter device 103 side even in a state where the filter 16 is clogged and the flow path resistance increases.

Although the case where the external filter device 103 is separate from the refrigerant circulation device 2 has been described here, the refrigerant circulation device 2 and the external filter device 103 may be integrated. In this case, the discharge portion 64 of the primary filter 6 is directly connected to the filter 16 without the coupling 14 interposed therebetween. The return portion 65 of the primary filter 6 is directly connected to the pump 15 without the coupling 14 interposed therebetween.

The discharge portion of the secondary filter 9 is directly connected to the filter 16 without the coupling 14 interposed therebetween. The return portion of the secondary filter 9 is directly connected to the pump 15 without the coupling 14 interposed therebetween. The filter 16 and the pump 15 connected to the primary filter 6 are different from the filter 16 and the pump 15 connected to the secondary filter 9, respectively.

Thus, the refrigerant circulation device 2 includes a primary return path for filtering the refrigerant discharged from the primary filter 6 and returning the filtered refrigerant to the primary pipe 3, and a secondary return path for filtering the refrigerant discharged from the secondary filter 9 and returning the filtered refrigerant to the secondary pipe 4.

Thus, the worker can easily perform maintenance work of the primary filter 6 and the secondary filter 9 without attaching the external filter device 103 to the refrigerant circulation device 2.

Note that the present technology can have configurations such as the following.
(1)

A refrigerant circulation device including: a primary pipe through which a primary refrigerant flows; a secondary pipe through which a secondary refrigerant flows; a primary filter connected to the primary pipe; a secondary filter connected to the secondary pipe; and a housing to accommodate the primary pipe, the secondary pipe, the primary filter, and the secondary filter, wherein the primary filter includes: a primary brush located inside the primary filter, and a primary handle to drive the primary brush, the secondary filter includes: a secondary brush located inside the secondary filter, and a secondary handle to drive the secondary brush, and the primary handle and the secondary handle are located at positions opposing a first side of the housing.
(2)

The refrigerant circulation device according to (1), further comprising, an expansion tank connected to the secondary pipe, wherein the expansion tank includes a regulating valve to regulate a pressure inside the expansion tank, and the regulating valve is located at a position opposing the first side surface of the housing.
(3)

The refrigerant circulation device according to (1) or (2), further including: a primary flow rate sensor to detect a flow rate of the refrigerant flowing through the primary pipe; and a secondary flow rate sensor to detect a flow rate of the refrigerant flowing through the secondary pipe, wherein the primary flow rate sensor and the secondary flow rate sensor are located at positions opposing a second side surface opposing the first side surface of the housing.
(4)

The refrigerant circulation device according to any one of (1) to (3) further comprising a display, wherein the first side surface of the housing is a door, and the display is on the door.
(5)

The refrigerant circulation device according to any one of (1) to (4) further including a pump connected to the secondary pipe, wherein the pump is located at a position where a motor assembly of the pump opposes the first side surface of the housing.
(6)

The refrigerant circulation device according to (5) further including a heat exchanger connected to the primary pipe and the secondary pipe, wherein the heat exchanger is located at a position lower than the pump inside the housing.
(7)

The refrigerant circulation device according to (2), wherein the primary handle, the secondary handle, and the regulating valve are located at positions higher than a center of the housing in a height direction.
(8)

The refrigerant circulation device according to (5) or (6), further including: a plurality of the pumps connected in parallel, and a merging pipe to merge the secondary refrigerant output from each of the pumps, wherein the secondary filter is connected to a downstream side of a merging point of the secondary refrigerant in the merging pipe.
(9)

The refrigerant circulation device according to any one of (1) to (8), wherein extending directions of rotation shafts of the primary handle and the secondary handle are a horizontal direction.
(10)

The refrigerant circulation device according to any one of (1) to (9), wherein the primary filter and the secondary filter each include: a filter portion, a discharge portion through which the refrigerant is discharged from the filter portion, and a return portion to return the filtered refrigerant returning from an external filter device to filter the refrigerant discharged from the discharge portion to the primary pipe or the secondary pipe.
(11)

The refrigerant circulation device according to (10), wherein the discharge portion and the return portion are located at positions facing the first side surface of the housing.
(12)

The refrigerant circulation device according to (10) or (11), wherein the discharge portion and the return portion are connected to the external filter device via couplings.
(13)

The refrigerant circulation device according to any one of (10) to (12), wherein the return portion is provided on a downstream side of a connection position of the primary filter in the primary pipe and on a downstream side of a connection position of the secondary filter in the secondary pipe.
(14)

The refrigerant circulation device according to any one of (10) to (13), wherein the external filter device includes a filter and a pump connected to a pipe through which the refrigerant flows, and the filter is connected on an upstream side of a connection position of the pump in the pipe.
(15)

The refrigerant circulation device according to (5) or (6), further including a first pipe to connect inflow portions of the refrigerant in a plurality of the pumps arranged side by side along a first direction and the secondary pipe to each other, wherein the first pipe includes: an extension pipe extending in a second direction orthogonal or substantially orthogonal to the first direction from each pump, a collecting pipe extending in a direction parallel or substantially parallel to the first direction and connected to a plurality of the extension pipes, and a connecting pipe extending in a vertical direction from the collecting pipe and connecting the collecting pipe and the secondary pipe to each other.
(16)

The refrigerant circulation device according to (5) or (6) further including a second pipe to connect outflow portions of the refrigerant in the plurality of pumps arranged side by side along a first direction and the secondary pipe to each other, wherein the second pipe includes: an extension pipe extending in a vertical direction from each pump, a collecting pipe extending in a direction parallel or substantially parallel to the first direction and connected to a plurality of the extension pipes, and a connecting pipe extending in a second direction orthogonal or substantially orthogonal to the first direction from the collecting pipe and to connect the collecting pipe and the secondary pipe to each other.
(17)

A refrigerant circulation device including: a primary pipe through which a primary refrigerant flows; a secondary pipe through which a secondary refrigerant flows; a primary filter connected to the primary pipe; a secondary filter connected to the secondary pipe; and a housing to accommodate the primary pipe, the secondary pipe, the primary filter, and the secondary filter; a primary return path to filter a refrigerant discharged from the primary filter and returning the refrigerant to the primary pipe; and a secondary return path to filter a refrigerant discharged from the secondary filter and returning the refrigerant to the secondary pipe, wherein the primary filter includes: a primary brush located inside the primary filter, and a primary handle to drive the primary brush; the secondary filter includes: a secondary brush located inside the secondary filter; and a secondary handle to drive the secondary brush, and the primary handle and the secondary handle are located at positions opposing a first side of the housing.

Further effects and modifications can be easily derived by those skilled in the art. Thus, the present disclosure in its broader aspects is not limited to the specific details and representative example embodiments illustrated and described above. Accordingly, various modifications may be made without departing from the spirit or scope of the general inventive concept as defined by the appended claims and their equivalents.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A refrigerant circulation device comprising:
a primary pipe through which a primary refrigerant flows;
a secondary pipe through which a secondary refrigerant flows;
a primary filter connected to the primary pipe;
a secondary filter connected to the secondary pipe; and
a housing to accommodate the primary pipe, the secondary pipe, the primary filter, and the secondary filter; wherein
the primary filter includes:
a primary brush located inside the primary filter; and
a primary handle to drive the primary brush;
the secondary filter includes:
a secondary brush located inside the secondary filter; and
a secondary handle to drive the secondary brush; and
the primary handle and the secondary handle are located at positions opposing a first side of the housing.

2. The refrigerant circulation device according to claim 1, further comprising:
an expansion tank connected to the secondary pipe; wherein
the expansion tank includes a regulating valve to regulate a pressure inside the expansion tank; and
the regulating valve is located at a position opposing the first side surface of the housing.

3. The refrigerant circulation device according to claim 1, further comprising:
a primary flow rate sensor to detect a flow rate of the refrigerant flowing through the primary pipe; and
a secondary flow rate sensor to detect a flow rate of the refrigerant flowing through the secondary pipe; wherein
the primary flow rate sensor and the secondary flow rate sensor are located at positions opposing a second side surface opposing the first side surface of the housing.

4. The refrigerant circulation device according to claim 1, further comprising:
a display; wherein
the first side surface of the housing is a door; and
the display is on the door.

5. The refrigerant circulation device according to claim 1, further comprising:
a pump connected to the secondary pipe; wherein
the pump is located at a position where a motor assembly of the pump opposes the first side surface of the housing.

6. The refrigerant circulation device according to claim 5, further comprising:
a heat exchanger connected to the primary pipe and the secondary pipe; wherein
the heat exchanger is at a position lower than the pump inside the housing.

7. The refrigerant circulation device according to claim 2, wherein
the primary handle, the secondary handle, and the regulating valve are located at positions higher than a center of the housing in a height direction.

8. The refrigerant circulation device according to claim 5, further comprising:
a plurality of the pumps connected in parallel; and
a merging pipe configured to merge the secondary refrigerant output from each of the plurality of pumps; wherein
the secondary filter is connected to a downstream side of a merging point of the secondary refrigerant in the merging pipe.

9. The refrigerant circulation device according to claim 1, wherein
extending directions of rotation shafts of the primary handle and the secondary handle, are a horizontal direction.

10. The refrigerant circulation device according to claim 1, wherein
the primary filter and the secondary filter each include:
a filter portion;
a discharge portion through which the refrigerant is discharged from the filter portion; and
a return portion to return the filtered refrigerant returning from an external filter device to filter the refrigerant discharged from the discharge portion to the primary pipe or the secondary pipe.

11. The refrigerant circulation device according to claim 10, wherein
the discharge portion and the return portion are located at positions opposing the first side surface of the housing.

12. The refrigerant circulation device according to claim 10, wherein
the discharge portion and the return portion are connected to the external filter device via couplings.

13. The refrigerant circulation device according to claim 10, wherein
the return portion is provided on a downstream side of a connection position of the primary filter in the primary pipe and on a downstream side of a connection position of the secondary filter in the secondary pipe.

14. The refrigerant circulation device according to claim 10, wherein
the external filter device includes a filter and a pump connected to a pipe through which the refrigerant flows; and
the filter is connected on an upstream side of a connection position of the pump in the pipe.

15. The refrigerant circulation device according to claim 5, further comprising:
a first pipe configured to connect inflow portions of the refrigerant in a plurality of the pumps arranged side by side along a first direction and the secondary pipe to each other; wherein
the first pipe includes:
an extension pipe extending in a second direction orthogonal or substantially orthogonal to the first direction from each pump;
a collecting pipe extending in a direction parallel or substantially parallel to the first direction and connected to a plurality of the extension pipes; and
a connecting pipe extending in a vertical direction from the collecting pipe and configured to connect the collecting pipe and the secondary pipe to each other.

16. The refrigerant circulation device according to claim 5, further comprising:
a second pipe configured to connect outflow portions of the refrigerant in the plurality of pumps arranged side by side along a first direction and the secondary pipe to each other; wherein
the second pipe includes:
an extension pipe extending in a vertical direction from each pump;
a collecting pipe extending in a direction parallel or substantially parallel to the first direction and connected to a plurality of the extension pipes; and
a connecting pipe extending in a second direction orthogonal or substantially orthogonal to the first direction from the collecting pipe and configured to connect the collecting pipe and the secondary pipe to each other.

17. A refrigerant circulation device comprising:
a primary pipe through which a primary refrigerant flows;
a secondary pipe through which a secondary refrigerant flows;
a primary filter connected to the primary pipe;
a secondary filter connected to the secondary pipe; and
a housing configured to accommodate the primary pipe, the secondary pipe, the primary filter, and the secondary filter;
a primary return path to filter a refrigerant discharged from the primary filter and return the refrigerant to the primary pipe; and
a secondary return path configured to filter a refrigerant discharged from the secondary filter and return the refrigerant to the secondary pipe; wherein
the primary filter includes:
a primary brush located inside the primary filter; and
a primary handle to drive the primary brush;
the secondary filter includes:
a secondary brush located inside the secondary filter; and
a secondary handle configured to drive the secondary brush; and
the primary handle and the secondary handle are located at positions opposing a first side of the housing.
